(19) United States
(12) Patent Application Publication
(10) Pub. No.: US 2026/0156857 A1
(43) Pub. Date: Jun. 4, 2026

(54) SEMICONDUCTOR DEVICE

(71) Applicant: NTT, Inc., Tokyo (JP)

(72) Inventors: Takuya Tsutsumi, Tokyo (JP); Fumito Nakajima, Tokyo (JP); Taro Sasaki, Tokyo (JP)

(21) Appl. No.: 19/136,505

(22) PCT Filed: Dec. 8, 2022
(86) PCT No.: PCT/JP2022/045267

§ 371 Date: Jun. 6, 2025

(51) Int. Cl. H10D 30/47; H10D 62/85; H10D 64/27; H10D 89/00

(52) U.S. Cl. CPC H10D 30/475; H10D 62/85; H10D 64/411; H10D 89/215

(57) ABSTRACT

An embodiment is a field effect transistor. The field effect transistor includes a channel layer, a channel control layer on the channel layer, a source electrode and a drain electrode on the channel control layer, a gate electrode on the channel control layer, the gate electrode between the source electrode and the drain electrode, and a sub-gate electrode on the channel control layer, the sub-gate electrode between the gate electrode and the drain electrode in the channel control layer.

### CROSS-REFERENCE TO RELATED APPLICATIONS

This application is a national phase entry of PCT Application No. PCT/JP2022/045267, filed on Dec. 8, 2022, which application is hereby incorporated herein by reference.

### TECHNICAL FIELD

The present invention relates to a semiconductor device having a field effect transistor structure.

### BACKGROUND

Regarding a technology using a terahertz wave, which is an electromagnetic wave frequency band of 0.3 to 3 THz, new applications such as high-speed wireless communication exceeding 100 Gbps, non-destructive internal inspection by three-dimensional imaging, component analysis using electromagnetic wave absorption, and atmospheric sensing from outer space have been searched and realized.

In order to realize the application due to the terahertz wave, an electronic device constituting the application is required to have better high frequency characteristics. As an electronic device having good high frequency characteristics, a field effect transistor made of a compound semiconductor having high electron mobility in physical properties is used. For further development of the terahertz wave technology in the future, a field effect transistor having better high frequency characteristics is required.

The field effect transistor includes a semiconductor (channel) layer, a gate electrode formed in the semiconductor (channel) layer, a source electrode formed on each of both sides of the gate electrode in a horizontal direction, and a drain electrode. In the field effect transistor, when a potential is applied to the gate electrode, carriers (electrons) traveling in the channel layer between the source electrode and the drain electrode are modulated corresponding to the intensity of the applied potential.

In order to improve the high frequency characteristics in the field effect transistor, it is necessary to increase a modulation speed in the channel layer. Examples of an index indicating the high frequency characteristics of the field effect transistor include a cutoff frequency (ft) and a maximum operation frequency (fmax). Among these, the improvement of the fmax is important from the viewpoint of amplification in an analog electronic circuit. The fmax represents a frequency at which the power gain of the field effect transistor is 1.

In order to improve the fmax in the field effect transistor, it is important to shorten the length (gate length) of the gate electrode.

In the field effect transistor, when a high bias is applied to the drain electrode, hot electrons are generated in the channel layer between the gate and the drain electrode. This creates electron-hole pairs and increases drain conductance. As a result, the fmax deteriorates. Therefore, in order to improve the fmax, it is also important to reduce the drain conductance.

Examples of the field effect transistor for improving the high frequency characteristics include a high electron mobility transistor (HEMT). The HEMT includes, as a semiconductor layer, a buffer layer, a channel layer, a barrier layer, and a cap layer and the like on a semiconductor substrate.

In the HEMT, carriers are supplied from a δ-doped layer formed in the barrier layer to the channel layer to form a two-dimensional electron gas, and a conduction channel between a source electrode and a drain electrode is formed. When a potential is applied to a gate electrode, the concentration of a two-dimensional electron gas is modulated corresponding to the intensity of the applied potential, and electrons move through the conduction channel between the source electrode and the drain electrode.

In the HEMT, the channel layer in which the two-dimensional electron gas is formed and the carriers travel and an electron supply layer into which impurities are introduced are spatially separated. As a result, in the HEMT, scattering or the like due to impurities is suppressed in the conduction channel, so that electron mobility can be improved and high frequency characteristics can be improved.

Therefore, in order to improve fmax in the HEMT, it is also important to shorten the length (gate length) of the gate electrode, reduce drain conductance, and apply a high-mobility material to a channel layer.

In a field effect transistor including an HEMT, shortening of a gate length is realized as a scaling technology.

In order to apply a high mobility channel layer in the HEMT, as illustrated in FIG. 7, a configuration is disclosed, in which a first channel layer 503 made of InGaAs having an In composition x of x≤0.8, a second channel layer 504 made of InGaAs or InAs having an In composition x of 0.8<x≤1, a third channel layer 505 made of InGaAs having a composition x of x≤0.8, a spacer layer 506 made of InAlAs, an electron supply layer 507, and a barrier layer 508 are formed in order (for example, Patent Literature 1). In addition, the configuration includes an InP substrate 501, a buffer layer 502 made of InAlAs, an etching stop layer 509 made of InP, an ohmic contact layer 510 made of InAlAs, and an ohmic contact layer 511 made of InGaAs.

In order to reduce drain conductance, as illustrated in FIG. 8, a configuration is disclosed, in which a structure (asymmetric recess structure) 612 having a space without a cap layer 606 in an asymmetric manner is formed such that a distance between a gate electrode 614 and a drain electrode 608 is longer than a distance between the gate electrode 614 and a source electrode 607 (Patent Literature 2). In addition, the configuration includes a substrate 601, a buffer layer 602, a channel layer 603, a barrier layer 604, an electron supply layer 605, a first insulating layer 609, an asymmetric recess forming opening 611, a second insulating layer 613, and a passivation layer 621.

Similarly, as illustrated in FIG. 9, an asymmetric recess structure 712/713 is disclosed, in which a cap layer 718 is removed such that a distance between a gate electrode 711 and a drain electrode 710 is longer than a distance between the gate electrode 711 and a source electrode 709 (Patent Literature 3). In addition, the structure includes a substrate 701, a buffer layer 702, a channel layer 703, a barrier layer 704, a passivation layer 705, an electron supply layer 708, an insulating film 714, and an opening 715.

According to these asymmetric recess structures, by intentionally causing carrier depletion in a drain electrode side region, it is possible to suppress the generation of hot electrons when a high drain bias is applied. As a result, drain conductance can be reduced, and fmax can be improved.

### CITATION LIST

### Patent Literature

Patent Literature 1: JP 5525013 B2
Patent Literature 2: JP 6810014 B2
Patent Literature 3: JP 5662547 B2

### SUMMARY

### Technical Problem

However, shortening the length (gate length) of the gate electrode in the field effect transistor causes a short channel effect such as a decrease in a threshold voltage, which is problematic.

In the configuration in which the high mobility channel layer is applied, a band gap in the high mobility channel material such as InAs is small, and thus hot electrons are significantly generated in the channel layer between the gate and drain electrodes when a high bias is applied to the drain electrode. This degrades the fmax.

In the configuration having the asymmetric recess structure, electrons are not induced in the barrier layer near the space where the cap layer is not provided in the drain electrode side region. As a result, the barrier layer in which the electrons are not induced is long, and thus drain resistance significantly increases. When the drain resistance increases, ft deteriorates, and thus the fmax greatly deteriorates.

As described above, even if the drain conductance is reduced by forming the space without the cap layer in the drain electrode side region to be long, the drain resistance increases so as to cancel the effect of improving the fmax. As a result, even if the asymmetric recess structure is applied, the fmax improving effect is limited to a certain extent, and a sufficient effect cannot be obtained.

### Solution to Problem

In order to solve the above-described problem, a semiconductor device according to the present invention is a field effect transistor including a gate electrode between a source electrode and a drain electrode, and carriers traveling between the source electrode and the drain electrode via a channel. The semiconductor device includes: a channel control layer disposed between the source electrode, the drain electrode, the gate electrode, and the channel; and a sub-gate electrode disposed between the gate electrode and the drain electrode in the channel control layer.

### Advantageous Effects of Invention

The present invention can provide a semiconductor device excellent in high frequency characteristics.

### BRIEF DESCRIPTION OF THE DRAWINGS

FIG. 1 is a schematic cross-sectional view illustrating a configuration of a semiconductor device according to a first embodiment of the present invention.

FIG. 2 is a schematic cross-sectional view illustrating an example of the configuration of the semiconductor device according to the first embodiment of the present invention.

FIG. 3 is a schematic cross-sectional view illustrating a configuration of a semiconductor device according to a second embodiment of the present invention.

FIG. 4 is a schematic cross-sectional view illustrating a configuration of a semiconductor device according to a third embodiment of the present invention.

FIG. 5 is a schematic cross-sectional view illustrating an example of the configuration of the semiconductor device according to the third embodiment of the present invention.

FIG. 6 is a schematic view illustrating a configuration of a semiconductor device according to a fourth embodiment of the present invention.

FIG. 7 is a schematic cross-sectional view illustrating a configuration of a conventional semiconductor device.

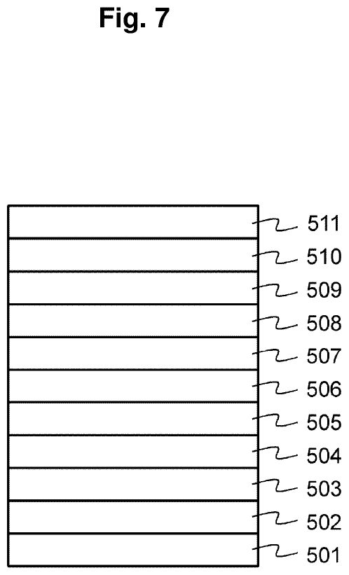

FIG. 8 is a schematic cross-sectional view illustrating a configuration of a conventional semiconductor device.

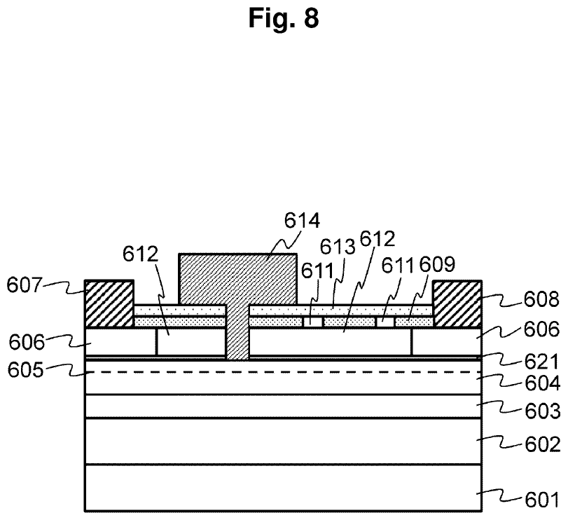

FIG. 9 is a schematic cross-sectional view illustrating a configuration of a conventional semiconductor device.

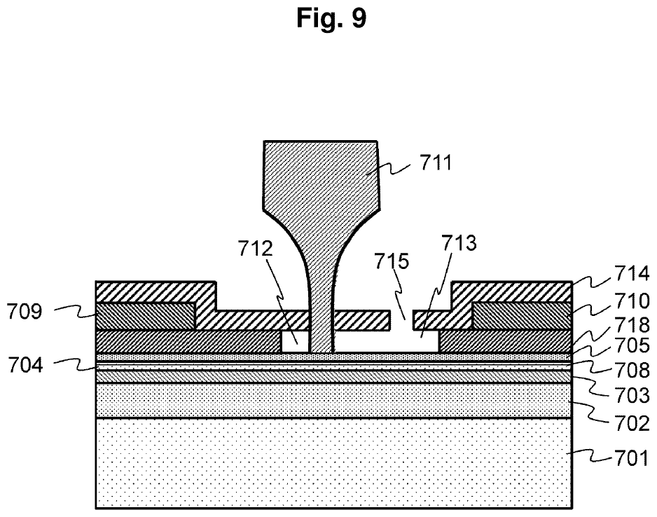

### DETAILED DESCRIPTION OF ILLUSTRATIVE EMBODIMENTS

### First Embodiment

A semiconductor device according to a first embodiment of the present invention will be described with reference to Fig

### <Configuration of Semiconductor Device>

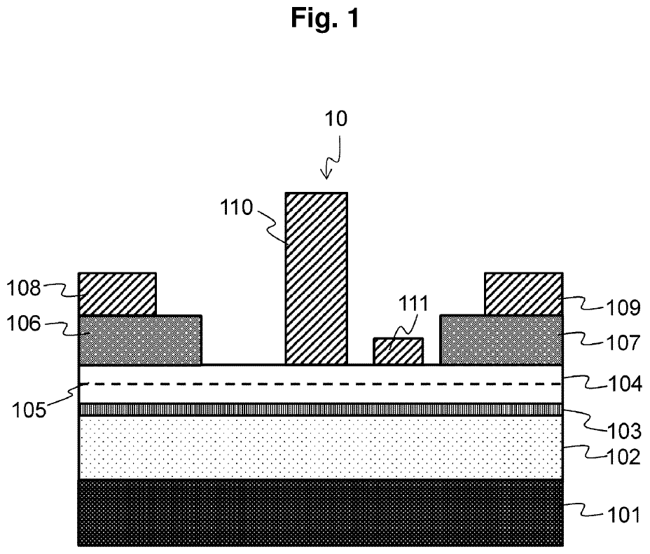

As illustrated in FIG. 1, a semiconductor device 10 according to the present embodiment includes a buffer layer 102, a channel layer 103, a barrier layer (hereinafter, also referred to as a “channel control layer”) 104, and cap layers 106 and 107 in this order from a substrate 101 side, and includes a δ-doped layer 105 in the barrier layer 104.

A source electrode 108 and a drain electrode 109, which are ohmic electrodes, are provided on the cap layers 106 and 107.

A gate electrode 110 is provided on the barrier layer 104 between the source electrode 108 and the drain electrode 109. Here, an example is shown in which the gate electrode 110 is disposed near the center between the source electrode 108 and the drain electrode 109, but the present invention is not limited thereto, and the gate electrode may be disposed at any position between the source electrode 108 and the drain electrode 109.

A sub-gate electrode 111 is provided on the barrier layer 104 between the gate electrode 110 and the drain electrode 109. Here, an example is shown in which the sub-gate electrode 111 is disposed near the center between the gate electrode 110 and the drain electrode 109, but the present invention is not limited thereto, and the sub-gate electrode may be disposed at any position between the gate electrode 110 and the drain electrode 109.

An InP-based HEMT will be described as an example of the semiconductor device 10 according to the present embodiment. Here, the InP-based HEMT is generally applied to a high-frequency HEMT in many cases.

In the InP-based HEMT, the buffer layer 102 is a buffer region provided when a crystal is grown on the semiconductor (InP) substrate 101. Non-doped InAlAs or the like is generally used as the material of the buffer layer, and the thickness thereof is about 5 to 1000 nm.

The channel layer 103 functions as a channel through which carriers travel between the source electrode 108 and the drain electrode 109, and is a region where the carriers are modulated by an electric field from the gate electrode 110. As electron mobility in the channel layer 103 is higher, high frequency performance can be enhanced. Non-doped InAs is used as the material of the channel layer. In addition, InxGa1-xAs or InSb or the like can be used. A composite channel structure in which different composition structures are stacked can also be applied. The total thickness of the channel layer 103 is about 3 to 20 nm.

The barrier layer (channel control layer) 104 is a region for forming a Schottky junction with the gate electrode 110. InP is used as the material of the barrier layer. In addition, a material having a band gap larger than the band gap of the channel layer 103 and capable of forming a sufficiently high Schottky barrier with respect to the gate electrode 110, such as InAlAs or InxGa1-xAs, can be used. Composite barrier structures having different compositions can also be applied. The total thickness of the barrier layer 104 is set to approximately ¼ to ⅕ or less of the gate length. For example, when the gate length is 50 nm, the thickness of the barrier layer 104 is 10 nm or more and 12.5 nm or less.

The δ-doped layer 105 is formed in a sheet shape in order to supply carriers in the barrier layer 104 which is non-doped. The dopant is n-type doping impurity Si or the like. The δ-doped layer 105 in the barrier layer 104 is formed substantially in the vicinity of the middle in the thickness direction of the barrier layer 104 (described later).

The cap layers 106 and 107 are formed to realize a low-resistance ohmic junction without performing an annealing treatment on the source electrode 108 and the drain electrode 109 which are ohmic electrodes, respectively. N-type InP is used as the material of the cap layers. In addition, InAlAs or InGaAs or the like can be used. The thickness of the cap layers 106 and 107 is set so that a sufficiently low contact resistance can be realized. An external parasitic capacitance can be structurally reduced, and is, for example, 5 to 20 nm.

The source electrode 108 and the drain electrode 109, which are ohmic electrodes, are formed to conduct carriers such as electrons to the channel layer 103 via the cap layers 106 and 107 and the barrier layer 104, and have a metal laminated structure. A stacked structure of Ti/Pt/Au is used as the metal stacked structure. In addition, Mo, W, or WSi or the like may be used for the stacked structure.

The gate electrode 110 is formed to modulate electrons and the like in the channel layer 103 by an electric field through the barrier layer 104, and has a metal laminated structure similarly to the source electrode 108 and the drain electrode 109. A stacked structure of Ti/Pt/Au is used as the metal stacked structure. In addition, Mo, W, or WSi or the like may be used for the stacked structure.

The length (gate length) of the gate electrode 110 is set to about 4 to 5 times the thickness of the barrier layer 104.

The sub-gate electrode 111 is formed on the barrier layer 104 between the source electrode 108 and the drain electrode 109, and has a metal stacked structure similarly to the gate electrode 110. A stacked structure of Ti/Pt/Au is used as the metal stacked structure. In addition, Mo, W, or WSi or the like may be used for the stacked structure.

### <Effects>

The effects of the semiconductor device 10 according to the present embodiment will be described.

In the semiconductor device 10, a sub-gate voltage different from the gate voltage is applied to the sub-gate electrode 111 to control the drift speed of carriers traveling between the gate electrode 110 and the drain electrode 109. Details thereof will be described below.

For example, a case will be considered, in which a conventional semiconductor device is operated under a bias condition in which a potential difference V_{gs} between a gate and a source and a potential difference Vas between a drain and the source are respectively V_{gs}=−0.2 V and V_{ds}=1.2 V. At this time, a potential difference V_{gd} between the gate and the source is 1.4 V. Furthermore, in a high-frequency application, an RF signal having a predetermined input power Pᵢₙ is input from the gate electrode 110 via a bias tee.

As described above, when a voltage is applied only to the source electrode 108, the drain electrode 109, and the gate electrode 110, the electric field concentrates at the drain end (end portion on the drain side) of the gate electrode 110, and electrons as conductive carriers are strongly accelerated to the drain side. At this time, new electron-hole pairs other than the conductive carriers is generated by the generation of hot carriers. That is, impact ionization occurs. As a result, drain conductance increases, and high-frequency characteristics deteriorate.

Meanwhile, in the semiconductor device 10 according to the present embodiment, by applying a DC voltage having a potential to reduce the drift speed of electrons to the sub-gate electrode 111, the generation of electron-hole pairs between the gate electrode 110 and the drain electrode 109 can be suppressed, and an increase in the drain conductance can be suppressed. As a result, the high frequency performance can be improved.

Here, a voltage applied to the sub-gate electrode 111 is set based on the band gap E_{g, ch} of a conductive channel material.

The impact ionization significantly occurs between the gate electrode 110 and the drain electrode 109 when the energy Eₑₗ of electrons satisfies the condition represented by Expression (1).

$$\begin{matrix}[ Math . 1 ] & \\ {E}_{el} > {E}_{g , ch} & ( 1 )\end{matrix}$$

By applying the sub-gate voltage V_{gsub} so as not to satisfy this condition and satisfying the condition represented by Expression (2), the impact ionization can be suppressed.

$$\begin{matrix}[ Math . 2 ] & \\ {E}_{el} - q {σ}_{gsub} {V}_{gsub} < {E}_{g , ch} & ( 2 )\end{matrix}$$

Here, a sub-gate electrode structure factor σ_{gsub} is a factor that depends on the structure of the sub-gate electrode 111, and satisfies Expression (3). The sub-gate electrode structure factor σ_{gsub} depends on, for example, the thickness of the barrier layer 104 in which the sub-gate electrode 111 is disposed, and the sub-gate electrode structure factor σ_{gsub} increases as the thickness of the barrier layer decreases (described later).

$$\begin{matrix}[ Math . 3 ] & \\ 0 < {σ}_{gsub} < 1 & ( 3 )\end{matrix}$$

Eₑₗ is simplified by Expression (4).

$$\begin{matrix}[ Math . 4 ] & \\ {E}_{el} = q {σ}_{g} {V}_{gd} & ( 4 )\end{matrix}$$

Here, q represents a charge element amount, and σ_{g} represents a factor depending on a gate electrode structure (gate electrode structure factor).

Similarly to the sub-gate electrode structure factor σ_{gsub}, the gate electrode structure factor σ_{g} satisfies Expression (5). For example, depending on the thickness of the barrier layer 104 in which the gate electrode 110 is disposed, the gate electrode structure factor σ_{g} increases as the thickness of the barrier layer decreases (described later).

$$\begin{matrix}[ Math . 5 ] & \\ 0 < {σ}_{g} < 1 & ( 5 )\end{matrix}$$

From Expression (2), a basic condition under which the impact ionization does not occur is represented by Expression (6).

$$\begin{matrix}[ Math . 6 ] & \\ q {σ}_{g} {V}_{gd} - q {σ}_{gsub} {V}_{gsub} < {E}_{g , ch} & ( 6 )\end{matrix}$$

Expression (7) is derived from Expression (6).

$$\begin{matrix}[ Math . 7 ] & \\ {V}_{gsub} > \frac{{σ}_{g}}{{σ}_{gsub}} {V}_{gd} - \frac{{E}_{g , ch}}{q {σ}_{gsub}} & ( 7 )\end{matrix}$$

Therefore, if V_{gsub} is set so as to satisfy Expression (7), the impact ionization can be suppressed.

For example, when V_{gd}=1.4 V and E_{g, ch}=0.8 eV are set, and σ_{g}=σ_{gsub}=0.5 is set for simplification, V_{gsub} may be set to be greater than about −0.2 V.

The sub-gate voltage V_{gsub} used when the semiconductor device 10 is operated is determined such that, for example, the semiconductor device 10 is operated using V_{gsub} set in advance on the basis of Expression (7) to perform high frequency measurement, and good fmax is obtained.

According to the semiconductor device of the present embodiment, the electric field intensity in the vicinity of the drain end of the gate electrode can be relaxed by applying the voltage to the sub-gate electrode, so that the generation of hot electrons can be suppressed, and the drain conductance can be reduced. As a result, the fmax can be improved.

In particular, the configuration of the semiconductor device according to the present embodiment is effective in an HEMT having a high mobility channel with a shortened gate length and a small band gap such as InAs. As a result, in the HEMT having the shortened gate length and the high mobility channel, the drain conductance can be reduced, and the fmax can be improved.

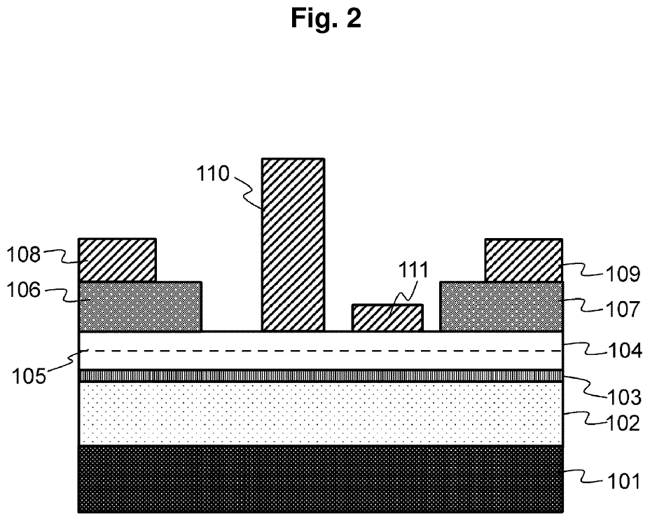

In the present embodiment, by way of example, the sub-gate electrode 111 is formed between the gate electrode 110 and the drain electrode 109 with the interval between the gate electrode 110 and the source electrode 108 substantially equal to the interval between the gate electrode 110 and the drain electrode 109. However, the present invention is not limited thereto. As illustrated in FIG. 2, the interval between the gate electrode 110 and the drain electrode 109 may be wider than the interval between the gate electrode 110 and the source electrode 108, and the sub-gate electrode 111 may be formed between the gate electrode 110 and the drain electrode 109.

As a result, the distance between the gate electrode 110 and the source electrode 108 is shortened, so that the relative source resistance can be reduced. Furthermore, since the distance between the gate electrode 110 and the drain electrode 109 is long, the sub-gate electrode 111 can be easily formed, and a more optimal sub-gate length can be set.

### Second Embodiment

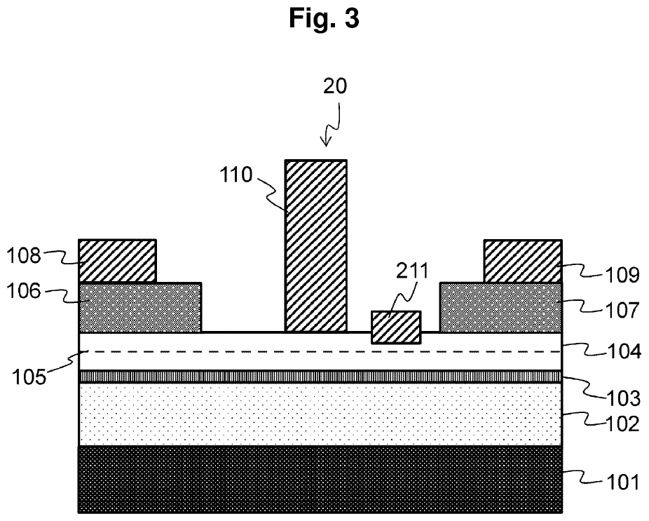

A semiconductor device according to a second embodiment of the present invention will be described with reference to FIG. 3.

### <Configuration of Semiconductor Device>

In a semiconductor device 20 according to the present embodiment, as shown in FIG. 3, a barrier layer 104 has a recess in a part (one region) of its surface, and a sub-gate electrode 211 is formed in the recess of the barrier layer 104. As a result, the barrier layer 104 immediately below the sub-gate electrode 211 is thin.

Here, the depth of the recess of the barrier layer 104 may be smaller than the thickness of the barrier layer 104. The depth of the recess in the barrier layer 104 is desirably smaller than a depth at which a δ-doped layer 105 is disposed. For example, when the thickness of the barrier layer 104 is about 10 nm, the depth of the recess of the barrier layer 104 is set to 2 to 8 nm.

The other configurations are the same as those of the first embodiment.

The sub-gate electrode 211 in the semiconductor device 20 is produced by forming a recess in a predetermined region of the surface of the barrier layer 104 by etching and then forming the sub-gate electrode 211.

### <Effects>

The effects of the semiconductor device 20 according to the present embodiment will be described based on an example of the operation of the semiconductor device.

In the operation of the semiconductor device 20, for example, similarly to the first embodiment, V_{gd}=1.4 V and E_{g, ch}=0.8 eV are set, and σ_{g}=0.5 is set for simplification. In the semiconductor device 20, the barrier layer 104 immediately below the sub-gate electrode 211 is thin, and thus a sub-gate electrode structure factor σ_{gsub} is set to about 0.75 (0.5 in the first embodiment).

In this case, a sub-gate voltage V_{gsub} is set to be greater than about −0.13 V. The sub-gate voltage can be set lower by about 35% than V_{gsub}>−0.20 V in the first embodiment. As described above, power saving can be achieved in a structure in which a sub-gate voltage is applied in addition to a gate voltage.

According to the semiconductor device of the present embodiment, hot electrons can be controlled with higher sensitivity, and power saving can be achieved.

In the present embodiment, by way of example, the entire sub-gate electrode 211 is formed in the recess of the barrier layer 104. However, the present invention is not limited thereto. A part of the sub-gate electrode 211 may be formed in the recess of the barrier layer 104.

### Third Embodiment

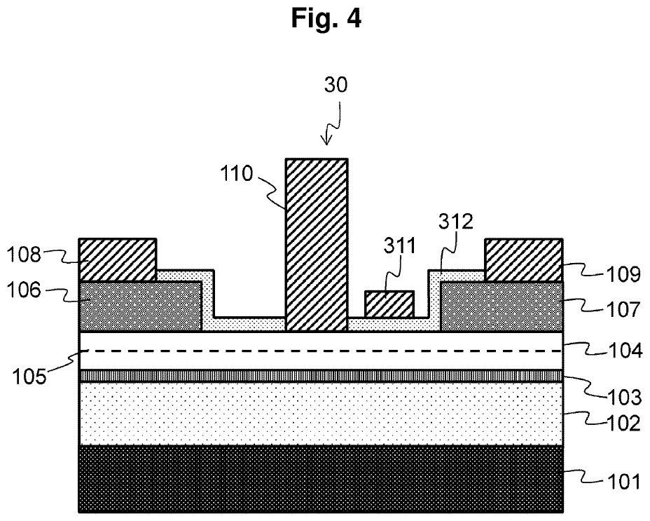

A semiconductor device according to a third embodiment of the present invention will be described with reference to FIG. 4.

### <Configuration of Semiconductor Device>

As illustrated in FIG. 4, a semiconductor device 30 according to the present embodiment includes a gate insulating film 312 on surfaces of a barrier layer 104 and cap layers 106 and 107 between a source electrode 108 and a gate electrode 110, and on the surfaces of the barrier layer 104 and cap layers 106 and 107 between a drain electrode 109 and the gate electrode 110.

The semiconductor device 30 includes a sub-gate electrode 311 on the gate insulating film 312 between the drain electrode 109 and the gate electrode 110.

The gate insulating film 312 is made of a high dielectric material, and for example, Al₂O₃, HfO₂, ZrO₂, or HfSiO, or the like is used. The thickness of the gate insulating film 312 is 2 to 20% of the barrier thickness.

The other configurations are the same as those of the first embodiment.

According to the semiconductor device of the present embodiment, a gate leakage current is reduced, and the effective barrier layer under the sub-gate electrode can be thinned by a depletion layer having an MIS structure, so that an effective distance between the sub-gate electrode and the channel layer can further be shortened. As a result, hot electrons can be controlled with higher sensitivity, and power saving can be achieved.

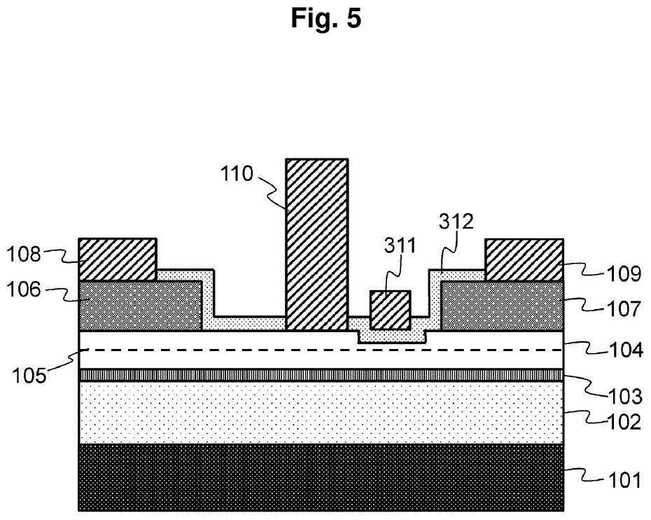

In the present embodiment, as illustrated in FIG. 5, a recess may be formed in a predetermined region of the surface of barrier layer 104 in the semiconductor device, and the sub-gate electrode 311 may be formed in the recess with the gate insulating film 312 interposed therebetween. Here, a part of the sub-gate electrode 311 may be formed in the recess of the barrier layer 104 with the gate insulating film 312 interposed therebetween. Accordingly, power saving can be further achieved.

### Fourth Embodiment

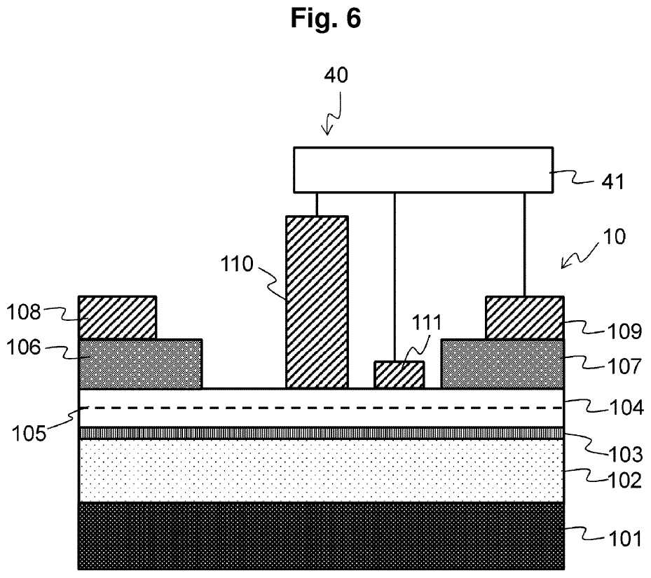

A semiconductor device according to a fourth embodiment of the present invention will be described with reference to FIG. 6.

### <Configuration of Semiconductor Device>

As illustrated in FIG. 6, a semiconductor device 40 according to the present embodiment includes a bias adjustment circuit 41 connected to a gate electrode 110, a sub-gate electrode 111, and a drain electrode 109 in a semiconductor device 10 according to the first embodiment.

The bias adjustment circuit 41 is formed around the gate electrode 110, the sub-gate electrode 111, and the drain electrode 109.

The bias adjustment circuit 41 automatically determines a sub-gate voltage based on a potential difference between the gate electrode 110 and the drain electrode 109.

Specifically, Expression (8) is obtained from Expression (7).

$$\begin{matrix}[ Math . 8 ] & \\ {V}_{gsub} ( {V}_{ds} , {V}_{gs} ) > \frac{{σ}_{g}}{{σ}_{gsub}} {V}_{gd} - \frac{{E}_{g , ch}}{q {σ}_{gsub}} = \frac{{σ}_{g}}{{σ}_{gsub}} ( {V}_{ds} - {V}_{gs} ) - \frac{{E}_{g , ch}}{q {σ}_{gsub}} & ( 8 )\end{matrix}$$

Here, σ_{g}, σ_{gsub}, and E_{g, ch} are constant in a uniform transistor.

In consideration of the fact that σ_{g} and σ_{gsub} depend on an electromagnetic field distribution that affects the channel from the gate electrode 110 and the sub-gate electrode 111, respectively in advance, a mechanism that feeds back to V_{gsub} may be attached to the bias adjustment circuit 41.

According to the semiconductor device of the present embodiment, the sub-gate voltage can automatically be determined, and the electric field intensity in the vicinity of the drain end of the gate electrode can be relaxed by the sub-gate voltage, so that the generation of hot electrons can be suppressed, and drain conductance can be reduced. As a result, the fmax can be improved.

By way of example, the present embodiment is applied to the semiconductor device according to the first embodiment, but the present invention is not limited thereto, and may be applied to the semiconductor devices according to the second and third embodiments.

The embodiments of the present invention show examples of the structures, dimensions, materials, and the like of the components in the configuration, manufacturing method, and the like of the semiconductor device, but the present invention is not limited thereto. The semiconductor device is only required to exhibit its functions and achieve its effects.

### INDUSTRIAL APPLICABILITY

The present invention relates to a semiconductor device having a field effect transistor structure, and can be applied to technologies using a terahertz wave, such as high-speed wireless communication, non-destructive internal inspection, material analysis, and atmospheric sensing.

### REFERENCE SIGNS LIST

10 Semiconductor device
103 Channel
104 Channel control layer
108 Source electrode
109 Drain electrode
110 Gate electrode
111 Sub-gate electrode

1-6. (canceled)

7. A field effect transistor comprising:
a channel layer;
a channel control layer on the channel layer;
a source electrode and a drain electrode on the channel control layer;
a gate electrode on the channel control layer, the gate electrode between the source electrode and the drain electrode; and
a sub-gate electrode on the channel control layer, the sub-gate electrode between the gate electrode and the drain electrode in the channel control layer.

8. The field effect transistor according to claim 7, wherein the sub-gate electrode is configured to control a speed of carriers traveling in the channel layer between the gate electrode and the drain electrode.

9. The field effect transistor according to claim 7, wherein an interval between the gate electrode and the source electrode is wider than an interval between the gate electrode and the drain electrode.

10. The field effect transistor according to claim 7, wherein:
the channel control layer includes a recess disposed in at least a part of a surface of the channel control layer in contact with the sub-gate electrode, and
the recess is filled with at least a part of the sub-gate electrode.

11. The field effect transistor according to claim 7, further comprising:
a gate insulating film at least between the sub-gate electrode and the channel control layer.

12. A semiconductor device comprising:
the field effect transistor according to claim 7; and
a bias adjustment circuit connected to the gate electrode, the sub-gate electrode, and the drain electrode.

13. The field effect transistor according to claim 8, wherein an interval between the gate electrode and the source electrode is wider than an interval between the gate electrode and the drain electrode.

14. The field effect transistor according to claim 10, further comprising a gate insulating film at least between the sub-gate electrode and the channel control layer.

15. A semiconductor device comprising:
the field effect transistor according to claim 8; and
a bias adjustment circuit connected to the gate electrode, the sub-gate electrode, and the drain electrode.

16. A semiconductor device comprising:
a field effect transistor comprising:
a channel layer;
a channel control layer disposed on the channel layer;
a source electrode and a drain electrode, respectively, formed on the channel control layer;
a gate electrode formed on the channel control layer, the gate electrode disposed between the source electrode and the drain electrode;
a sub-gate electrode formed on the channel control layer, the sub-gate electrode disposed between the gate electrode and the drain electrode;
a gate insulating film provided at least between the sub-gate electrode and the channel control layer;
wherein the channel control layer includes a recess disposed in at least a part of a surface of the channel control layer in contact with the sub-gate electrode, and at least a portion of the recess is filled with at least a part of the sub-gate electrode;
wherein an interval between the gate electrode and the drain electrode is wider than an interval between the gate electrode and the source electrode; and
wherein the sub-gate electrode is configured to control a speed of carriers traveling in the channel layer between the gate electrode and the drain electrode by application of a voltage to the sub-gate electrode; and
a bias adjustment circuit connected to the gate electrode, the sub-gate electrode, and the drain electrode.

17. The semiconductor device according to claim 16, wherein the gate insulating film is made of a high dielectric material selected from the group consisting of Al₂O₃, HfO₂, ZrO₂, and HfSiO₄.

18. The semiconductor device according to claim 16, wherein the channel layer is made of a material selected from the group consisting of InAs, InxGa1-xAs, and InSb.

19. The semiconductor device according to claim 16, wherein the channel control layer is made of a material selected from the group consisting of InP, InAlAs, and InxGa1-xAs.

20. The semiconductor device according to claim 16, wherein the bias adjustment circuit is configured to automatically determine a sub-gate voltage based on a potential difference between the gate electrode and the drain electrode.

21. The semiconductor device according to claim 16, wherein the gate insulating film has a thickness of 2% to 20% of a thickness of the channel control layer.

22. The semiconductor device according to claim 16, further comprising:
a δ-doped layer formed in the channel control layer.

23. The semiconductor device according to claim 22, wherein the δ-doped layer is formed in a middle in a thickness direction of the channel control layer.
